(19) United States
(12) Patent Application Publication
(10) Pub. No.: US 2024/0418792 A1
(43) Pub. Date: Dec. 19, 2024

(54) BATTERY HEALTH DETERMINATION APPARATUS AND METHOD

(71) Applicant: ROLLS-ROYCE plc, London (GB)

(72) Inventors: Tomasz Marek LUBECKI, Singapore (SG); Apple ANG, Singapore (SG); Chee Wei LEE, Singapore (SG)

(73) Assignee: ROLLS-ROYCE plc, London (GB)

(21) Appl. No.: 18/738,941

(22) Filed: Jun. 10, 2024

(30) Foreign Application Priority Data
Jun. 16, 2023 (GB) 2309065.7

(51) Int. Cl. G01R 31/392; G01R 19/02; G01R 31/36; G01R 31/385; G01R 31/389; H01M 50/51

(52) U.S. Cl. CPC G01R 31/392; G01R 19/02; G01R 31/3644; G01R 31/386; G01R 31/389; H01M 50/51

(57) ABSTRACT

An apparatus for determining the health of a battery including a plurality N of series-connected cells. The apparatus includes an AC signal source operable to cause an AC current to flow through one or more cells of the plurality of series-connected cells, a current measurement unit operable to measure the AC current, a voltage measurement unit operable to measure an AC voltage induced across the one or more cells by the AC current, and a health determination unit operable to determine a measurement of the health of the battery based on the measured AC current and the measured AC voltage.

This specification is based upon and claims the benefit of priority from UK Patent Application Number 2309065.7 filed on 16 Jun. 2023, the entire contents of which are incorporated herein by reference.

### BACKGROUND

### Technical Field

The present disclosure relates to an apparatus for determining the health of a battery and methods of the same.

### Background of the Disclosure

DC batteries may comprise a set of series-connected battery cells (or cells) enclosed in a package, used for providing power to a range of different electrical machines. The voltage ratings of series-connected cells cumulatively form the rated output voltage of the battery. Batteries, and battery cells, are consumable components that degrade over time as they undergo increasing numbers of charge and discharge cycles. Degradation of the battery cells affects battery performance by limiting a usable capacity of the battery (i.e., a total amount of charge that may be stored) and the maximum output power (i.e., output voltage, output current). Over time, the usable capacity of the battery and the maximum output power tends to decrease. In applications where the battery must be reliable, or in applications where safety is paramount, knowing the health (the so-called battery health), or condition, of the battery is important. Various tests may be performed on the battery to measure its electrical properties and ensure it performs according to its rated capacity, output voltage, etc. Results of the tests may indicate that the battery should be replaced.

In order to monitor battery health over time, parameters which describe the state or condition of the battery, such as State of Health Capacitance and State of Health Resistance—so-called SOH-C and SOH-R—may be determined. A battery (or cells of the battery) may (each) have a small internal resistance causing a small voltage drop across the battery itself, reducing the rated output voltage. A value of the internal resistance may change (i.e., increase) over time and may be used as a measure of the health of the battery. These parameters may be derived from measurements of physical/electrical properties of the battery, or a particular cell of the battery, and include the internal or parasitic impedance, capacitance or resistance of the battery or cell, and may be indirectly measured using specialised equipment. However, in applications where the battery contains a large number of cells, and/or where the voltage of the battery is relatively high (e.g., hundreds or thousands of volts), existing methods of measuring battery operating parameters are often not practical.

It is desirable to provide improvements to existing battery health determination methods and apparatuses in the light of the above.

### SUMMARY

In a first arrangement, there is provided an apparatus for determining the health of a battery comprising a plurality N of series-connected cells. The apparatus comprises an AC signal source operable to cause an AC current to flow through one or more cells of the plurality of series-connected cells, a current measurement unit operable to measure the AC current, a voltage measurement unit operable to measure an AC voltage induced across the one or more cells by the AC current, and a health determination unit operable to determine a measurement of the health of the battery based on the measured AC current and the measured AC voltage.

The value of N may be such that N≥20, or N≥50, or N≥80, or N≥100, or N≥200, or N≥400, or N≥800.

The N series-connected cells may be connected in series between terminals of the battery, and may be configured, when charged, to generate a potential difference VB across the battery terminals. The AC current may be configured such that the peak-to-peak voltage VPP of the AC voltage is small compared to VB.

X may be the ratio VB/VPP, and the value of X may be such that X≥100, or X≥200, or X≥400, or X≥800. The value of X may be such that X≥N, or X≥2N, or X≥4N.

The health determination apparatus may be further operable to determine an impedance of the one or more cells based on the measured AC current and the measured AC voltage. The health determination apparatus may be further operable to determine the measurement of the health of the battery based on the determined impedance.

The health determination apparatus may be further operable to calculate RMS current and voltage values based on the measured AC current and the measured AC voltage, respectively. The health determination apparatus may be further operable to calculate the measurement of the health of the battery based on the RMS current and voltage values.

The signal source may be operable to cause the AC current to flow through the one or more cells. The signal source may be external to or separate from the battery. The signal source may be configured to superimpose the AC current on a DC current provided by the one or more cells and/or by the plurality N of series-connected cells.

The signal source may be coupled to terminals of the battery, or to the one or more cells, to cause the AC current to flow through the one or more cells, optionally using a switch.

The signal source may be coupled to the terminals of the battery, or to the one or more cells, via a DC decoupling component or an AC coupling component. The DC decoupling component or AC coupling component may comprise a capacitor and/or a transformer.

The signal source may cause the AC current to flow through the N series-connected cells.

The health determination unit may be further operable to measure a plurality of AC voltages, each induced across a respective one or more cells of the N series-connected cells by the AC current. The health determination unit may be further operable to determine a measurement of the health of the battery based on the measured AC current and at least two of the measured AC voltages.

Said plurality of AC voltages may comprise N AC voltages each induced across a respective one of the N series-connected cells by the AC current.

The signal source may comprise a totem-pole arrangement of transistors and a controller operable to control the transistors so that the totem-pole arrangement functions as an oscillator, the totem-pole arrangement optionally connected to a transformer. The signal source may comprise an AC signal generator connected to an amplifier. The signal source may comprise an inductor and a switch connected in series and a controller operable to control the switch so that the inductor and switch function as an oscillator.

The apparatus for determining the health of a battery may comprise said battery.

In a second arrangement, there is provided a vehicle, or a propulsion unit or power unit therefor, or a power supply or containerized power supply, comprising the apparatus for determining the health of a battery of the first arrangement. The vehicle may be an aircraft, seacraft or spacecraft.

In a third arrangement, there is provided a method of determining the health of a battery comprising a plurality N of series-connected cells. The method comprises causing an AC current to flow through one or more cells of the plurality of series-connected cells, measuring the AC current, measuring an AC voltage induced across the one or more cells by the AC current, and determining a measurement of the health of the battery based on the measured AC current and the measured AC voltage.

The value of N may be such that N≥20, or N≥50, or N≥80, or N≥100, or N≥200, or N≥400, or N≥800.

The N series-connected cells may be connected in series between terminals of the battery and may be configured, when charged, to generate a potential difference VB across the battery terminals. The AC current may be configured such that the peak-to-peak voltage VPP of the AC voltage is small compared to VB.

X may be the ratio VB/VPP, and the value of X may be such that X≥100, or X≥200, or X≥400, or X≥800. The value of X may be such that X≥N, or X≥2N, or X≥4N.

The method of determining the health of a battery may comprise determining an impedance of the one or more cells based on the measured AC current and the measured AC voltage. The method of determining the health of a battery may comprise determining the measurement of the health of the battery based on the determined impedance.

The skilled person will appreciate that except where mutually exclusive, a feature described in relation to any one of the above aspects may be applied mutatis mutandis to any other aspect. Furthermore, except where mutually exclusive any feature described herein may be applied to any aspect and/or combined with any other feature described herein.

### BRIEF DESCRIPTION OF THE DRAWINGS

Embodiments will now be described by way of example only with reference to the accompanying drawings, which are purely schematic and not to scale, and in which:

FIG. 1 is a schematic block diagram of an apparatus 100 for determining the health of a battery comprising a plurality N of series-connected cells, embodying the present invention;

FIG. 2 is a schematic block diagram of an apparatus 200 for determining the health of a battery comprising a plurality N of series-connected cells, embodying the present invention;

FIG. 3 is a schematic block diagram of an apparatus 300 for determining the health of a battery comprising a plurality N of series-connected cells, embodying the present invention;

FIG. 4 is a flow diagram showing the steps of a method 400, embodying the present invention;

FIG. 5 is a flow diagram showing the steps of a method 500, embodying the present invention;

FIG. 6 is a flow diagram showing the steps of a method 600, embodying the present invention;

FIG. 7 is a flow diagram showing the steps of a method 700, embodying the present invention;

FIG. 8 is a schematic diagram of signal source circuitry 800;

FIG. 9 is a schematic diagram of signal source circuitry 900; and

FIG. 10 is a schematic diagram of signal source circuitry 1000.

### DETAILED DESCRIPTION

The present invention relates generally to apparatuses and methods for determining the health of a battery comprising a plurality of series-connected cells.

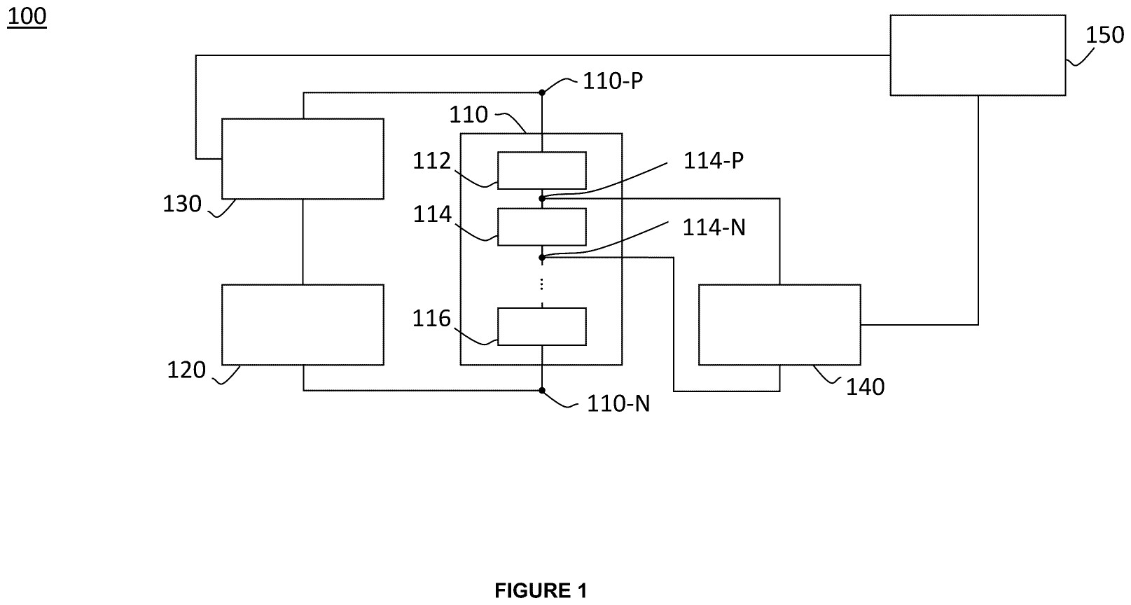

FIG. 1 is a block diagram of an apparatus 100 for determining the health of a battery 110 comprising a plurality N of series-connected cells, embodying the present invention. The number N may be considered to be an integer and to be greater than or equal to two. In some arrangements the battery 110 may form part of the apparatus 100, however it will be understood that the apparatus 100 may be provided separately from the battery 110.

The apparatus 100 comprises an AC signal source 120 operable to cause an AC current to flow through one or more cells 114 of the plurality N of series-connected cells 112, 114, 116 (of the battery 110), a current measurement unit 130 operable to measure the AC current, a voltage measurement unit 140 operable to measure an AC voltage induced across the one or more cells 114 by the AC current and a health determination unit 150 operable to determine a measurement of the health of the battery 110 based on the measured AC current and the measured AC voltage. The signal source 220 is configured to superimpose the AC current on a DC current provided by the one or more cells 114 and/or by the plurality N of series-connected cells 112, 114, 116.

Advantages of the present embodiment may be appreciated by making comparison to a comparative example in which a DC input signal is used to measure properties of the battery.

In the comparative example, a DC battery comprises 100 series-connected cells, where each cell has a voltage of 4V and an internal resistance of 10 mΩ, providing a DC battery with a total output voltage of 400V and an internal resistance of 1Ω. In order to measure the internal resistance of the battery (and/or of individual cells), a DC input signal equal to the voltage of the battery (i.e., a 400V DC input signal) is supplied across the terminals of the battery which induces a noticeable voltage variation across each cell. For example, to generate an additional potential difference of 10 mV across each cell, a 400V DC input signal with a current of 1 A may be supplied, where the noticeable voltage variation of 10 mV across each cell is realised by 1 A*10mΩ. Therefore, across the entire 400V DC battery, the input DC signal must deliver 400 W of power (400V DC*1A).

According to the present embodiment, apparatus 100 causes an AC signal to be superimposed on the DC signal of (i.e., supplied by) the battery. Again, it is assumed that each cell has a voltage of 4V and an internal resistance of 10 mΩ. By supplying an AC input signal across the terminals of the battery, and targeting a noticeable voltage variation of 10 mV RMS across each cell of the battery, a 1V RMS 1A RMS AC signal may be supplied to the terminals of the battery (i.e., superimposed on the DC signal of the battery). The 1V RMS AC signal is split across each of the 100 cells to impose a variation of 10 mV RMS AC across each cell. The AC input signal however draws only 1 W of power (1V RMS*1A RMS).

It can be seen that by using an AC input signal, the power delivered by the input signal across the terminals of the battery in order to determine battery health may be significantly reduced.

Additionally, the AC input signal is DC voltage independent (when the total impedance of the battery remains the same). The battery may be rated at 400V, 800V, or over 1 kV, without a noticeable effect on the AC voltage variation seen over each cell (when the impedance of the cells, rated at e.g., 4V, 8V and 10V in the 400V, 800V and 1 kV battery respectively, remains the same). According to the conventional example, the power delivered by the DC input signal will increase as the rated DC voltage of the battery increases.

In some embodiments, N≥20, or N≥50, or N≥80, or N≥100, or N≥200, or N≥400, or N≥800. It will be understood that as the number of cells in the battery increases, the total voltage of the battery will increase, placing a larger burden on the power supplied by conventional DC input signals used to interrogate the battery's operating conditions. The advantages of the present invention are therefore greater when determining the health of a battery with a larger number of cells, since the reduction in required input signal power is greater.

Further, the current measurement unit and voltage measurement unit need only be capable of measuring a relatively small AC current (which is typically not supplied by the battery, but which is supplied by the signal source) and small AC voltage. Determination of these values may be performed with relatively low voltage-rated equipment, saving power and space, where measurement devices capable of measuring high currents and high voltages are typically large devices.

Regarding the voltage levels of the AC input signal relative to the DC voltage level of the battery, the N series-connected cells may be connected in series between terminals of the battery and configured, when charged, to generate a potential difference V_{B} across the battery terminals, and the AC current may be configured such that the peak-to-peak voltage V_{PP} of the superimposed AC voltage is small compared to V_{B}.

In some arrangements, X may be the ratio V_{B}/V_{PP} wherein X≥10, or X≥20, or X≥100, or X≥200, or X≥400, or X≥800, and/or X≥N, or X≥2N, or X≥4N.

In some arrangements, each cell of the N series-connected cells has a potential difference of V_{CELL}, the battery has a potential difference of V_{B}=N*V_{CELL}, and the AC current is configured such that the peak-to-peak voltage V_{PP} of the AC signal is at least one order of magnitude smaller than V_{B}. Optionally, X may be the ratio V_{B}/V_{PP}, and X≥10, or X≥20, or X≥100, or X≥200, or X≥400, or X≥800, or X≥N, or X≥2N, or X≥4N.

Such a configuration allows the use of relatively small AC signals (AC input signal, AC current and AC voltage) compared to relatively large DC voltages of the battery.

Further, a particularly degraded cell in the battery is often considered as the weakest link in the battery system and may pose a risk to the overall working of the battery if left undetected. Existing testing methods may measure properties of the battery as a whole, and may not detect problems with individual cells. However, arrangements disclosed herein consider measuring a voltage across one or more cells of the N series-connected cells, or even over each of the N series-connected cells. In some embodiments, the health of an individual cell or of each of the cells may be determined. Measurements taken in respect of individual cells may enable a more focussed and detailed assessment of the battery.

While not necessarily forming part of the apparatus 100, the structure of a DC battery 110 will be described in order to understand how the apparatus 100 interfaces with such a battery. The N series-connected cells of the battery 110 are shown enclosed within battery 110, with cell 112 representing a first cell, cell 114 representing a second cell and cell 116 representing an N-th cell. Cell 114 and cell 116 are separated by ellipses indicating the presence of additional intermediate cells (e.g., a third cell to an N−1-th cell). Battery 110 has a positive terminal 110-P (positioned at the top of battery 110 with respect to FIG. 1) and a negative terminal 110-N (positioned at the bottom of battery 110 with respect to FIG. 1). The N series-connected cells of the battery 110 are connected in series between the positive terminal 110-P of the battery 110 and the negative terminal 110-N of the battery 110. Cell 114, in this arrangement representing the one or more cells of the N series-connected cells, has a positive terminal 114-P (positioned at the top of the cell 114) and a negative terminal 114-N (positioned at the bottom of the cell 114). The other cells in the battery 110 may also be considered to have their own corresponding positive and negative terminals (not shown) in the same way as described in relation to cell 114. The polarity of the terminals of the (each) cell may match the polarity of the terminals of the battery. Terminals of the N series-connected cells may be accessible via tap points in the battery structure i.e., externally accessible connections positioned between adjacent cells, allowing connections to measurement devices external to the battery 110. Alternatively, connections may be made to existing battery monitoring devices, or Integrated Circuits (ICs), internal to the battery which are capable of measuring voltages across one or more battery cells, and which may output voltage measurements to external systems.

It should be noted that any cell, e.g., cell 112, may represent/be implemented as multiple (smaller) cells connected in parallel. These parallel connected cells collectively form a single cell with the operating voltage and current of one of the series connected cells of the battery. Similarly, any cell, e.g., cell 112, may represent/be implemented as multiple (smaller) cells connected in series. Combinations of parallel and series connections are envisaged. Such an arrangement will be understood with respect to any of the apparatuses and methods described herein.

The battery 110 may be removeable/replaceable within the apparatus 100 in order to perform health determination of different batteries. Alternatively, the apparatus 100 may be permanently connected to the battery or contained within the battery housing, enabling a determination of the health of the battery to be performed at any time.

The polarity of the terminals (denoting the orientation or current direction of the battery 110 and/or the cells 112, 114, 116) have been shown in FIG. 1 with positive terminals at the top and with negative terminals at the bottom, with respect to the arrangement of FIG. 1. However, it will be understood that the battery 110 (and the cells within the battery) may be connected to the apparatus 100 in a reverse orientation, where the negative terminals are at the top and positive terminals are at the bottom.

The signal source 120 is operable to cause an AC current to flow through one or more cells 114 of the N series-connected cells 112, 114, 116. In the arrangement in FIG. 1, the signal source 120 is connected to the negative terminal 114-N of the one or more cells 114 (via the negative terminal 110-N of the battery 110) and to the positive terminal 114-P of the one or more cells 114 (via the current measurement unit 130 and the positive terminal 110-P of the battery 110). The signal source 120 is operable to supply an AC input signal along one of its connections (e.g., along the connection to the positive terminal of the one or more cells 114) in order to cause an AC current to flow through the one or more cells 114.

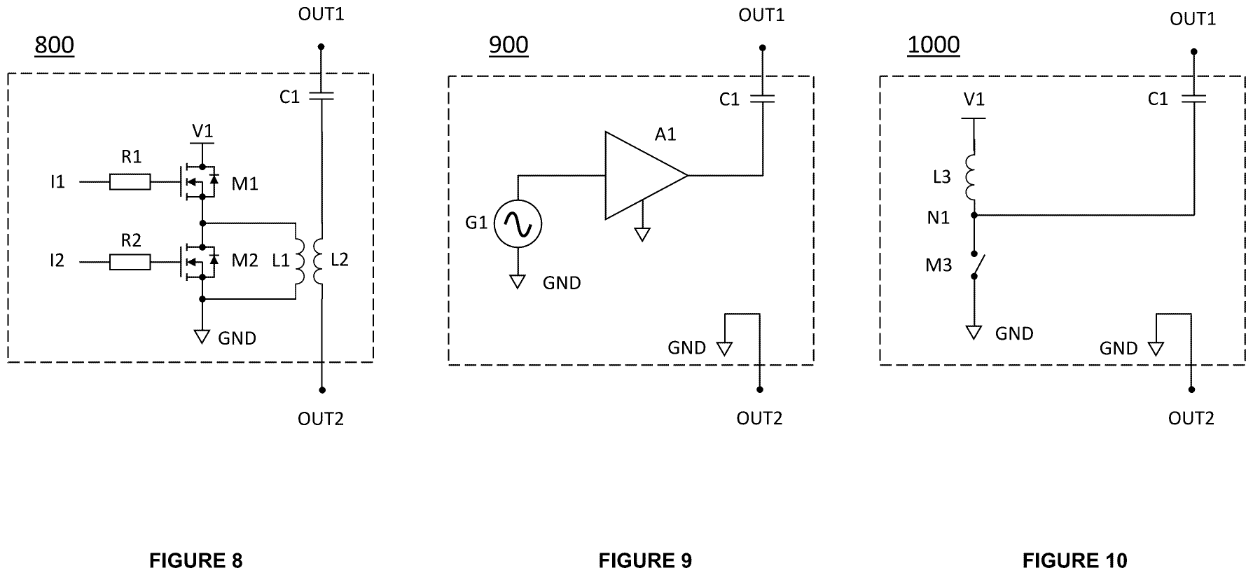

Examples of signal source 120 are shown in FIGS. 8, 9 and 10, and are described in detail later.

The current measurement unit 130 is operable to measure the AC current, and output the measured AC current to the health determination unit 150. The current measurement unit 130 is connected in series between the signal source 120 and the positive terminal 114-P of the one or more cells 114 (via the positive terminal 110-P of the battery 110). In an alternative arrangement, the current measurement unit 130 may be connected in series between the signal source 120 and the negative terminal 114-N of the one or more cells 114 (possibly via the negative terminal 110-N of the battery 110), or in any other arrangement such that the current measurement unit 130 may measure the current flowing through the one or more cells 114.

The current measurement unit may output a measure of current in Amps.

It will be understood that since the cells in the battery 110 are connected in series, the current passing through one cell will be the same as the current passing through each other cell, and through the battery 110 as a whole. Therefore, the current measurement unit 130, while shown as being connected in series with the entire battery 110 in FIG. 1, could be connected at any position in series with the one or more cells 114 (i.e., between cells of the battery).

The current measurement unit 130 may be an ammeter (an AC ammeter). Alternatively, the current measurement unit may provide an indirect measurement of current, using, for example, a current mirror-type circuit. The current measurement unit 130 may provide a measurement of current derived by measuring a voltage drop over a known shunt resistance connected to the one or more cells, or battery. Measurements of current may also be derived using additional circuitry connected to/in/around the current carrying path of the one or more cells, or battery, such as a Rogowski coil, where the current carrying path may induce a voltage in the Rogowski coil which may be used to derive a value of the current in the current carrying path. Measurements of current may also be derived by connecting a first side of a transformer in series with the current carrying path, and measuring a corresponding current on a second side of the transformer, in order to indirectly measure an AC current flowing through the first side by measuring a stepped-down or stepped-up AC current on the second side, and using the turns ratio of the transformer to determine the current flowing on the first side. Measurements of current may also be derived based on current measurements taken by internal battery monitoring ICs. Such methods of measuring current are given merely as examples.

The voltage measurement unit 140 is operable to measure an AC voltage induced across the one or more cells 114 by the AC current, and output the measured AC voltage to the health determination unit 150. In FIG. 1, the voltage measurement unit 140 is connected to the positive terminal 114-P of the one or more cells 114 and the negative terminal 114-N of the one or more cells 114, in order to measure a voltage across the one or more cells 114. In an alternative arrangement, the voltage measurement unit 140 may be connected in any other arrangement such that it is connected in parallel with the one or more cells 114 over which a voltage is being measured.

The voltage measurement unit 140 may output a measure of voltage in Volts.

The voltage measurement unit 140 may be a voltmeter (an AC voltmeter). Measurements of voltage may also be derived based on voltage measurements taken by internal battery monitoring ICs. Measurements of voltage may be derived from an analogue-to-digital converter, or AC-DC converter (which may be part of the internal battery monitoring ICs). Such methods of measuring voltage are given merely as examples.

The health determination unit 150 is operable to determine a measurement of the health of the battery 110 based on the measured AC current and measured AC voltage. The health determination unit 150 is connected to the current measurement unit 130 and the voltage measurement unit 140.

In FIG. 1, the signal source 120 is configured to cause an AC current to flow in the one or more cells 114, by supplying an AC input signal to the positive terminal 114-P of the one or more cells 114 (via the current measurement unit 130 and the positive terminal 110-P of the battery). The AC current is measured by the current measurement unit 130 and a corresponding AC voltage (induced over the one or more cells by the supplied AC current) is measured by the voltage measurement unit 140 across the one or more cells 114. The measurements from the current measurement unit 130 and the voltage measurement unit 140 are output to the health determination unit 150 for determination of the health of the battery, in accordance with methods 400, 500, 600 and 700 described below.

In some embodiments, as mentioned above, the apparatus 100 may contain or comprise said battery 110, and the apparatus 100 may be packaged within the battery housing.

Of course, cell 114 is one example of the one or more cells of the battery 110. Any cell or group of cells of the N series-connected cells of the battery 110 may be considered the one or more cells, including, for example, cell 112 alone, or cells 112 and 114 in combination. In order to measure a voltage across any one or more cells of the N series-connected cells, the voltage measurement unit 140 should be connected to the positive terminal of a first cell of the one or more cells, and the negative terminal of a last cell of the one or more cells, wherein the one or more cells are a plurality of sequential series-connected cells within the N series-connected cells beginning at the first cell and ending at the last cell. In the case where the one or more cells is a single cell, the first and last cells may be the same cell (as seen in FIG. 1, cell 114). Of course, the voltage may be measured across a plurality of cells individually. Such an arrangement may enable a more focused assessment of the one or more cells.

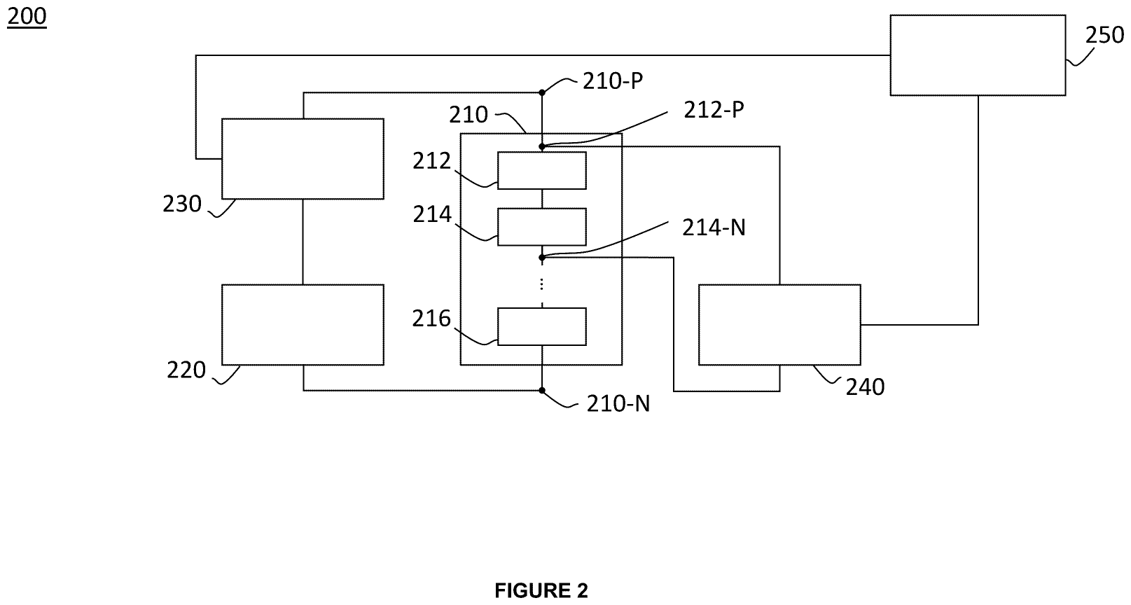

FIG. 2 is a block diagram of an apparatus 200 for determining the health of a battery 210 comprising a plurality N of series-connected cells, embodying the present invention. Apparatus 200 is similar to apparatus 100. Like elements are denoted by corresponding like reference signs, where reference sign 200 corresponds to reference sign 100 and so on and so forth, and repeat description will be omitted. In contrast to FIG. 2, the one or more cells comprise cells 212 and 214, and as such apparatus 200 represents an embodiment where the one or more cells of the battery 210 comprise more than one cell of the battery 210.

The signal source 220, current measurement unit 230 and battery health determination unit 250 are configured and connected in the same way as described in relation to FIG. 1. However, voltage measurement unit 240 is connected to measure an AC voltage across the cells forming the one or more cells, via connection to the positive terminal 212-P of a first cell 212, and the negative terminal 214-N of a second cell 214.

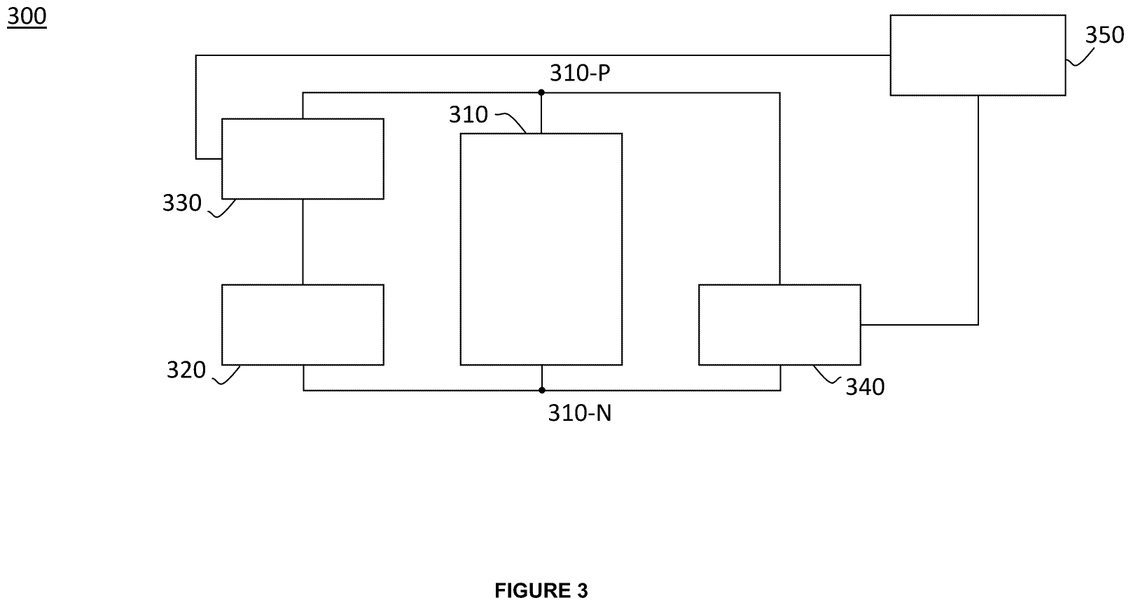

FIG. 3 is a block diagram of an apparatus 300 for determining the health of a battery 310 comprising a plurality N of series-connected cells, embodying the present invention. Apparatus 300 is similar to apparatus 100 and apparatus 200. Like elements are again denoted by corresponding like reference signs, where reference sign 300 corresponds to reference signs 100 and 200 and so on and so forth, and repeat description will be omitted. In contrast to FIG. 1, battery 310 is represented simply as a single block, and the voltage measurement unit 340 is connected to the positive terminal 310-P and negative terminal 310-N of the battery 310, and represents an embodiment where the one or more cells of the battery 310 comprise all (i.e., every cell) of the plurality N of series-connected cells of the battery 310. As before, the voltage may be measured across the plurality of cells individually.

The signal source 320, current measurement unit 330 and battery health determination unit 350 are configured and connected in the same way as described in relation to FIG. 1. However, voltage measurement unit 340 is connected to measure an AC voltage across the entire battery 310.

It should be understood that any additional functionality of apparatus 100 described below is also applicable to apparatus 200 and apparatus 300.

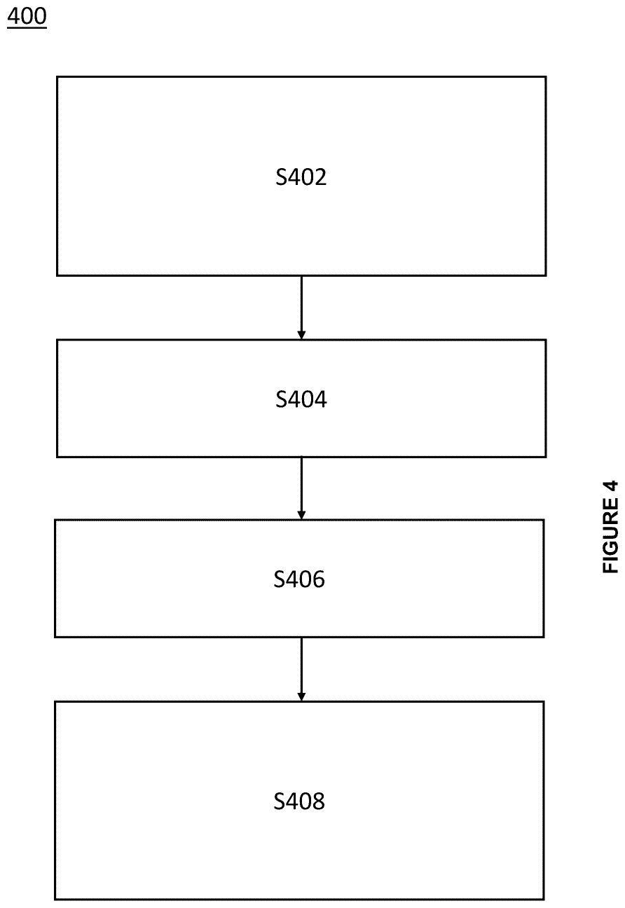

FIG. 4 is a flow diagram showing the steps of a method 400, embodying the present invention.

Method 400 determines the health of a battery comprising a plurality N of series-connected cells, in line with the use of apparatus 100, 200 or 300.

The method 400 comprises causing an AC current to flow through one or more cells of the plurality N of series-connected cells (step S402), measuring the AC current (step S404), measuring an AC voltage induced across the one or more cells by the AC current (step S406) and determining a measurement of the health of the battery based on the measured AC current and measured AC voltage (step S408).

Method 400 may comprise using the signal source to cause the AC current to flow through the one or more cells. The signal source may be external to or separate from the battery. For example, the battery may have a built-in signal generation unit for such purposes or may rely on an external device to supply the AC current to the battery. Method 400 may comprise using the signal source to superimpose the AC current on a DC current provided by the one or more cells and/or by the plurality N of series-connected cells.

In line with method 400, the signal source 120 may be operable to cause the AC current to flow through the one or more cells 114, i.e., to superimpose the AC current on the DC current of the battery, optionally wherein the signal source 120 is external to or separate from the battery 110. The signal source may be configured to superimpose the AC current on a DC current provided by the one or more cells and/or by the plurality N of series-connected cells.

Method 400 may comprise conductively coupling the signal source to terminals of the battery, or to the one or more cells, to cause the AC current to flow through the one or more cells. This may be achieved by using a switch or configurable switching circuitry.

In line with method 400, the signal source 120 may be coupled to terminals of the battery 110 (positive terminal 110-P and negative terminal 110-N), or to the one or more cells 114, to cause the AC current to flow through the one or more cells 114, optionally using a switch.

Method 400 may comprise conductively coupling the signal source to terminals of the battery, or to the one or more cells, via a DC decoupling component (an AC coupling component). That component may optionally comprise a capacitor and/or a transformer.

In line with method 400, the signal source 120 may be coupled to the terminals of the battery, or (e.g., directly) to the one or more cells 114, via a DC decoupling component or an AC coupling component, that component optionally comprising a capacitor and/or a transformer.

The DC decoupling component or AC coupling component may effectively block the flow of DC current and permit the flow of AC current, thereby to superimpose an AC signal on a DC signal of the battery.

Method 400 may comprise causing the AC current to flow through the N series-connected cells.

In line with method 400, the signal source 120 may cause the AC current to flow through the N series-connected cells.

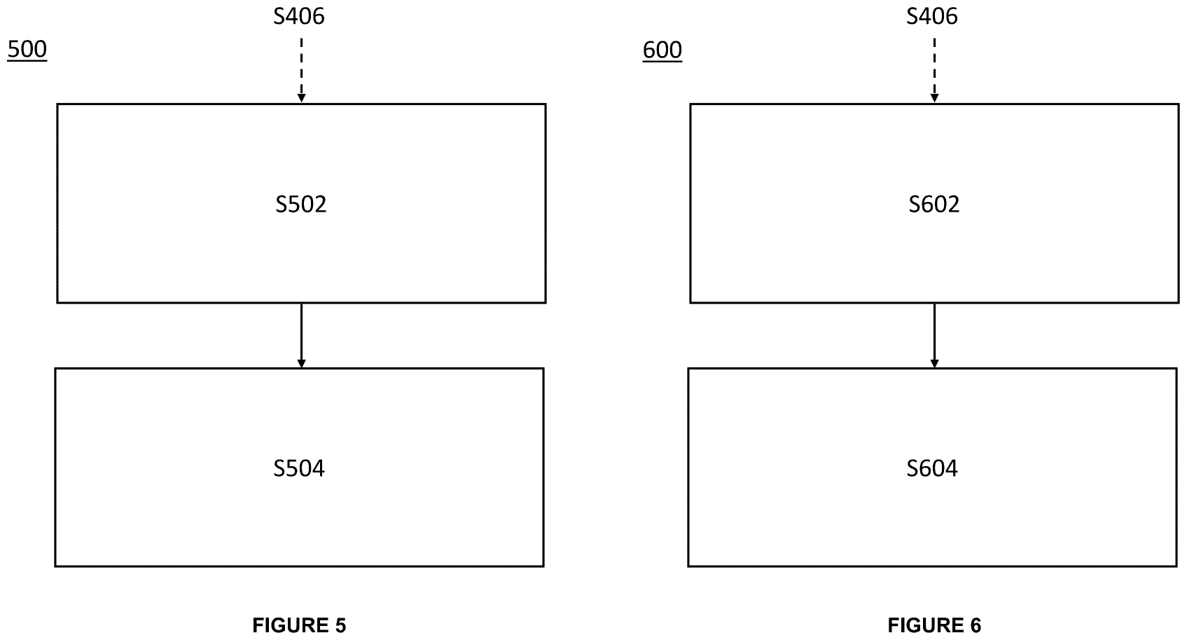

FIG. 5 is a flow diagram showing the steps of a method 500, embodying the present invention.

As indicated by the dashed arrow, the method 500 may begin from Step S406 of method 400 shown in FIG. 4 (after measuring the AC current and measuring the AC voltage induced across the one or more cells by the AC current), i.e., comprise steps S402, S404 and S406 in addition to those shown in FIG. 5.

Method 500 comprises determining an impedance of the one or more cells based on the measured AC current and the measured AC voltage (step S502) and determining the measurement of the health of the battery based on the determined impedance (step S506).

In line with method 500, apparatus 100 may be further operable to determine an impedance of the one or more cells based on the measured AC current and the measured AC voltage, and determine the measurement of the health of the battery based on the determined impedance.

An impedance (internal impedance, parasitic impedance, internal resistance, parasitic resistance) of the one or more cells of the battery may be determined using, for example, the following formula:

$$r = \frac{{V}_{ac}}{{I}_{ac}}$$

where r is the impedance of the one or more cells, V_{ac} is the measured AC voltage, and lac is the measured AC current.

After being determined, the impedance r may be used to determine a measurement of the health of the battery. The impedance value may itself be an indicator of the health of the battery, or a predetermined relationship between the impedance and another battery health property may exist. Such a relationship may be battery model or type specific and may take the form of a curve or look-up table, for example. The impedance may be used to determine a State of Health Resistance value. Alternatively, the impedance r of the one or more cells may be compared to a nominal/rated/previously measured impedance rₓ of the one or more cells, and a measurement of the health of the battery may be derived based on a ratio/difference/relationship between the impedance r and the nominal/rated/previously measured impedance rₓ. Alternatively, the impedance r may be input into an equation or formula to generate a normalised measurement of the health of the battery between an upper and lower limit of battery health, where the normalised measurement of the health of the battery is dependent on the impedance r. For example, the normalised measurement of the health of the battery may be a value between 0 and 100, or 10 and 20, which indicates the health of the battery. The measurement of the health of the battery may be used to indicate how healthy/unhealthy the one or more cells are, or indicate a remaining lifetime of the one or cells.

Where the one or more cells is a single cell, the impedance of that particular cell is determined, where V_{ac} is the measured AC voltage across that particular cell.

Where the one or more cells is a plurality of cells, the impedance of that particular plurality of cells is determined, where V_{ac} is the measured AC voltage across that particular plurality of cells. An impedance value for a single cell in the particular plurality of cells may be estimated by dividing the calculated impedance by the number of cells in the particular plurality of cells.

FIG. 6 is a flow diagram showing the steps of a method 600, embodying the present invention.

As indicated by the dashed arrow, the method may begin from Step S406 of method 400 shown in FIG. 4, i.e., comprise steps S402, S404 and S406 in addition to those shown in FIG. 6.

Method 600 comprises calculating RMS current and voltage values based on the measured AC current and the measured AC voltage, respectively (step S602) and determining the measurement of the health of the battery based on the RMS current and voltage values (step S604).

In line with method 600, apparatus 100 may be further operable to calculate RMS current and voltage values based on the measured AC current and the measured AC voltage, respectively, and calculate the measurement of the health of the battery based on the RMS current and voltage values.

RMS current and RMS voltage are the root-means-square current and voltage respectively, and may be derived from a value of the peak current (peak-to-peak current) measured by the current measurement unit 130 and peak voltage (peak-to-peak voltage) measured by the voltage measurement unit 140. Those skilled in the art will be aware of various methods of determining an RMS current and RMS voltage from an AC current or AC voltage signal, including, but not limited to:

$${V}_{rms} = \frac{1}{\sqrt{2}} {V}_{pp}$$

wherein Vᵣₘₛ is the RMS AC voltage and Vₚₚ is the peak-to-peak AC voltage, and where the AC input signal is a sinusoidal waveform.

RMS current and RMS voltage provide a type of average measurement which may be more indicative of the actual magnitude of the AC current and AC voltage, compared to a sample taken at some point along the fluctuating AC waveform. By using the RMS values, a more representative value of battery health may be determined.

Alternatively, multiple AC current measurements may be taken and an average AC current measurement may be determined. This average AC current measurement may be used in place of the RMS current.

Similarly, multiple AC voltage measurements may be taken and an average AC voltage measurement may be determined. This average AC voltage measurement may be used in place of the RMS voltage.

In one embodiment, the steps of methods 500 and 600 may be combined. For example, an impedance of the one or more cells may be derived based on the measured RMS current and RMS voltage, and a measurement of the health of the battery is determined based on the determined impedance.

An impedance of the one or more cells may be determined using the following formula:

$$r = \frac{{V}_{ac rms}}{{I}_{ac rms}}$$

wherein r is the impedance of the one or more cells, V_{ac rms} is the RMS voltage, and I_{ac rms} is the RMS current.

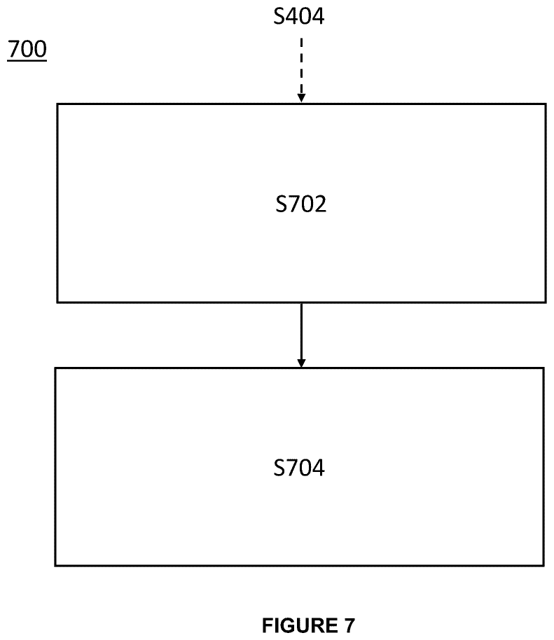

FIG. 7 is a flow diagram showing the steps of a method 700, embodying the present invention.

As indicated by the dashed arrow, the method 700 may begin from Step S404 of method 400 shown in FIG. 4 (after measuring the AC current), i.e., comprise steps S402 and S404 in addition to those shown in FIG. 7.

Method 700 comprises measuring a plurality of AC voltages, each induced across a respective one or more cells of the N series-connected cells by the AC current (step S702) and determining a measurement of the health of the battery based on the measured AC current and at least two of the measured AC voltages (step S704).

In line with method 700, the health determination unit 150 may be further operable to measure a plurality of AC voltages, each induced across a respective one or more cells of the N series-connected cells by the AC current, and determine a measurement of the health of the battery based on the measured AC current and at least two of the measured AC voltages.

The plurality of AC voltages may be measured concurrently, using for example, a plurality of voltage measurement units, connected to measure the voltage across a plurality of one or more cells concurrently (i.e., simultaneously, or at approximately the same time).

Said plurality of AC voltages may comprise N AC voltages induced across respective ones of the N series-connected cells by the AC current. For example, where a battery has a 20 series-connected cells, method 700 may measure 20 AC voltages—an AC voltage across each cell of the 20 series-connected cells—using 20 voltage measurement units.

Alternatively, the plurality of AC voltages may be measured sequentially, using for example, a single, reconfigurable voltage measurement unit 150, connected to measure the voltage across a plurality of one or more cells sequentially (i.e., one after the other). The voltage measurement unit 150 may be controllable via control means to electrically connect and disconnect from the terminals of the one or more cells in order to achieve the functionality of a plurality of voltage measurement units. Such an arrangement may enable a more granular and informative assessment of the state of health of the battery by measuring the state of health of each/every cell.

A measurement of the health of the battery may be determined based on the measured AC current and at least two of the measured AC voltages. The current flowing through the series-connected cells is the same, and so a plurality of measurements of health of the battery may be determined using a single measured AC current. The measurement of health may be an average value of the measurements of the health of the battery determined from the plurality of (i.e., at least two) measured AC voltages. Where a health measurement is determined for each of a plurality of cells, the health of the overall battery may be based on the health measurement for the cell which indicates the “worst” health.

While methods 500, 600 and 700 have been described separately, it will be apparent that combinations of such methods are possible. For example, the determination of an impedance (method 500) based on RMS current and RMS voltage (method 600) has already been considered. Measuring a plurality of AC voltages (method 700) where each measured AC voltage is an RMS voltage (method 600) is also considered. Measuring a plurality of AC voltages (method 700) and determining a plurality of impedances based on the measured AC voltages and a measured AC current (method 500) is also considered. Measuring a plurality of AC voltages (method 700) where each measured AC voltage is an RMS voltage (method 600), and determining a plurality of impedances based on the measured AC voltages and a measured AC current (method 500) is also considered.

FIGS. 8, 9 and 10 are circuit diagrams showing circuits 800, 900 and 1000 respectively, which are examples of signal sources 120, 220 and 320. It will be understood that any of circuits 800, 900 and 1000 may replace any of signal sources 120, 220 and 320 in FIGS. 1, 2 and 3.

FIG. 8 is a schematic diagram of signal source circuitry 800, a first signal source design.

The first signal source design comprises a ‘totem-pole’ arrangement of transistors and a controller operable to control the transistors so that the totem-pole arrangement functions as an oscillator. The totem-pole arrangement may be optionally connected to a transformer.

In signal source 800, the totem-pole arrangement of transistors comprises two transistors M1 and M2 connected in series (i.e., where a drain of transistor M1 is connected to a source terminal of transistor M2, or vice versa) between a first voltage node V1 and a second voltage node GND. The first voltage node V1 has a relatively high voltage (i.e., VCC, a positive voltage or around +1 v, +2 v or +5 v), and the second voltage node GND has a relatively low voltage (i.e., ground potential, −VCC, a negative voltage or 0 v, −1 v, −2 v, or −5 v). Gate terminals of transistors M1 and M2 are controlled by control signal inputs 11 and 12 via impedances R1 and R2 respectively.

Signal source circuitry 800 also comprises a transformer, shown in FIG. 8 as two coupled coils (inductors) L1 and L2. Coil L1 may be referred to as the low voltage side and is connected in parallel with transistor M2. Coil L2 may be referred to as the high voltage side. The transformer may be configured to step up a voltage from the low voltage side to the high voltage side according to a turns ratio of the transformer. For example, a voltage 1V at the low voltage side may be stepped up to a voltage 10V at the high voltage side where the turns ratio of the transformer is 10.

Coil L2 is connected in series between a first output node OUT1 (via a DC decoupling component or AC coupling component C1) and a second output node OUT2. First output node OUT1 denotes a first output node of the signal source circuitry 800, and second output node OUT2 denotes a second output node of the signal source circuitry 800.

As will be understood with reference to FIGS. 1 to 3, the first output node OUT1 represents a node for connection to the positive terminal 114-P of the one or more cells 114 of the N series-connected cells, or the positive terminal 110-P of the battery 110 (via the current measurement unit 130). The second output node OUT2 represents a node for connection to the negative terminal 114-N of the one or more cells 114 of the N series-connected cells, or the negative terminal 110-N of the battery 110.

The controller is configured to control the control signal inputs 11 and 12 to alternate between a first configuration in which a current flow increases through coil L1, and a second configuration in which the current flow decreases through coil L1.

In the first configuration, input control signal 11 is ON (HI, has a high voltage) causing the transistor M1 to turn ON, and input control signal 12 is OFF (LO, has a low voltage) causing the transistor M2 to turn OFF. A current will begin to flow from the first voltage node V1, through transistor M1 and coil L1, to the second voltage node GND, increasing with time as the transistor M1 turns fully ON. The current may be said to be flowing in a downward direction through coil L1 with respect to FIG. 8. An EMF is generated across coil L1, where a high potential is seen at the top of coil L1 (at the node between transistor M1 and transistor M2) and a low potential is seen at the bottom of coil L1 (connected to GND).

In the second configuration, input control signal 11 is OFF (LO) causing the transistor M1 to turn OFF, and input control signal 12 is ON (HI) causing the transistor M2 to turn ON. As a result of the EMF generated across the coil L1, a current will continue to flow through the coil L1 in the same downward direction as in the first configuration, but the current will decrease with time as the energy stored in the coil L1 decreases.

By alternating between the first and second configurations, a corresponding AC (or fluctuating) current is generated in coil L2.

The circuitry on the low voltage side of the transformer i.e., the circuitry connected to coil L1 (control signal inputs 11 and 12, impedances R1 and R2, transistors M1 and M2, first voltage source V1, second voltage source GND and inductor L1) collectively forms low-voltage circuitry. The circuitry on the high voltage side of the transformer i.e., the circuitry connected to coil L2 (inductor L2 and decoupling capacitor L2) collectively forms high-voltage circuitry.

Impedance/inductance values of coils L1 and L2, or collectively the transformer, may be configured for impedance matching between the low voltage circuitry and the high voltage circuitry. The transformer ratio may be selected such that the capacitance/size of the DC decoupling component or AC coupling component C1 (represented as a DC decoupling capacitor) is optimal for high-voltage applications. The RMS current value generated by signal source circuitry 800 will be proportional to (or defined by) the design parameters of the circuit (the first voltage source V1 etc.). The voltage generated on the high-voltage side of the transformer will be proportional to (or defined by) the internal resistance of the one or more cells of the battery.

FIG. 9 is a schematic diagram of signal source circuitry 900, a second signal source design.

The second signal source design comprises an AC signal generator connected to an amplifier.

Signal source circuitry 900 comprises an AC signal generator G1 connected to an input terminal of an amplifier A1. An output terminal of the amplifier A1 is connected to a DC decoupling component or AC coupling component C1, shown as a DC decoupling capacitor.

The AC signal generator G1 is connected between the input terminal of the amplifier A1 and a second voltage node GND. Second voltage node GND is configured in the same way as described in relation to FIG. 8. AC signal generator G1 is capable of generating an AC signal with known signal parameters (i.e., frequency, amplitude etc.) and may be controllable/programmable. The AC signal generator G1 may be a small signal generator. The AC signal generator G1 may be a digital-to-analogue converter or an oscillator or another form of digital switching circuit controllable to output a small AC signal.

The output terminal of the amplifier A1 supplies an amplified version of the AC signal (also with known frequency, and amplified amplitude) received from the AC signal generator G1 to the DC decoupling capacitor C1. Amplifier A1 may have an input voltage source (not shown) in order to power the amplifier, and a connection to ground. The amplifier A1 may be a Class AB amplifier, a Class A amplifier, a Class B amplifier, a Class D amplifier with a digital DC input signal, or other amplifier capable of amplifying an AC input signal.

The output terminal of the amplifier A1 is connected to a first output node OUT1 (via the DC decoupling capacitor C1). A second output node OUT2 is connected to the second voltage node GND. First output node OUT1 denotes a first output node of the signal source circuitry 900, and second output node OUT2 denotes a second output node of the signal source circuitry 900. The first and second outputs nodes OUT1 and OUT2 are configured for connection to components of the health determination apparatus 100, 200 or 300 as explained in relation to FIG. 8.

FIG. 10 is a schematic diagram of signal source circuitry 1000, a third signal source design.

The third signal source design comprises an inductor and a switch connected in series and a controller operable to control the switch so that the inductor and switch function as an oscillator.

Signal source circuitry 1000 comprises an inductor L3 and a switch M3 connected in series between a first voltage node V1 and a second voltage node GND. The first voltage node V1 and the second voltage node GND are configured as described in relation to FIG. 8. A DC decoupling component or AC coupling component C1, shown as a DC decoupling capacitor, is connected to a node N1 between the inductor L3 and the switch M3.

The controller is configured to control switch M3 to alternate between a first configuration in which the switch M3 is closed and in which the inductor L3 charges, and a second configuration in which the switch M3 is open and the inductor L3 discharges. Repeated charging and discharging of the inductor L3 causes an AC current to appear at the decoupling capacitor C1.

The charging and discharging of the inductor L3 may be considered a current flow. The gradients of the charge-discharge cycle of the inductor L3 (measured as charge over time) may be used to determine an induced current resulting from the internal or parasitic impedance/resistance of the one or more cells of the battery.

Node N1 is connected to a first output node OUT1 (via the DC decoupling component or AC coupling component C1). A second output node OUT2 is connected to the second voltage node GND. First output node OUT1 denotes a first output node of the signal source circuitry 1000, and second output node OUT2 denotes a second output node of the signal source circuitry 1000. The first and second output nodes OUT1 and OUT2 are configured for connection to components of the health determination apparatus 100, 200 or 300 as explained with reference to FIG. 8.

Switches M1 and M2 in FIG. 8, and switch M3 in FIG. 10 may be implemented by any type of controllable switching device including a solid-state switch, Field-Effect Transistor (e.g., a MOSFET), BJT, switching regulator, microcontroller or FPGA.

Voltage source V1 in FIG. 10 may be implemented by any voltage source or voltage conversion unit, including not but limited to a (constant) DC voltage source, DC-DC converter, voltage regulator or low-dropout regulator (LDO).

The signal source circuitry 1000 of FIG. 10 may be described as a Class F amplifier, used to generate high-frequency AC current signals.

It will be understood that other examples of signal generation circuitry may be used to generate an appropriate AC signal for use in the above-described methods and circuits.

Various examples have been described, each of which feature various combinations of features. It will be appreciated by those skilled in the art that, except where clearly mutually exclusive, any of the features may be employed separately or in combination with any other features and the invention extends to and includes all combinations and sub-combinations of one or more features described herein.

It will also be appreciated that the invention has been described broadly, and the techniques described herein could be used in many applications. These include, but are not limited to, aerospace, automotive, marine, sub-marine and land-based applications. For example, a vehicle, or a propulsion unit or power unit therefor, may comprise any of the apparatuses described herein. The vehicle may be an aircraft, seacraft or spacecraft. Alternatively, the techniques described herein may be applied to power systems in general i.e., containerised battery systems, or power banks comprising one or more batteries, used to supply power to any type of electrical system. Such containerised battery systems or power banks (power supply or containerized power supply) may be implemented in aerospace, automotive, marine, sub-marine, and land-based applications as described above.

In any of the above aspects, the various features may be implemented in hardware, or as software modules running on one or more processors/computers.

The invention also provides a computer program or a computer program product comprising instructions which, when executed by a computer, cause the computer to carry out any of the methods/method steps described herein, and a non-transitory computer-readable medium comprising instructions which, when executed by a computer, cause the computer to carry out any of the methods/method steps described herein. A computer program embodying the invention may be stored on a non-transitory computer-readable medium, or it could, for example, be in the form of a signal such as a downloadable data signal provided from an Internet website, or it could be in any other form.

The disclosure extends to the followings sets of numbered statements:
Y1. Apparatus for determining the health of a battery comprising a plurality N of series-connected cells, the apparatus comprising:
   an AC signal source operable to cause an AC current to flow through one or more cells of the plurality of series-connected cells;
   a current measurement unit operable to measure the AC current;
   a voltage measurement unit operable to measure an AC voltage induced across the one or more cells by the AC current; and
   a health determination unit operable to determine a measurement of the health of the battery based on the measured AC current and the measured AC voltage.
Y2. The apparatus of statement Y1, wherein N≥20, or N≥50, or N≥100, or N≥200, or N≥400, or N≥800.
Y3. The apparatus of statement Y1 or Y2, wherein:
   the N series-connected cells are connected in series between terminals of the battery and configured, when charged, to generate a potential difference V_{B} across the battery terminals; and
   the AC current is configured such that the peak-to-peak voltage V_{PP} of the AC voltage is small compared to V_{B}.
Y4. The apparatus of statement Y3, wherein X is the ratio V_{B}/V_{PP} and wherein:
   X≥100, or X≥200, or X≥400, or X≥800; and/or
   X≥N, or X≥2N, or X≥4N.
Y5. The apparatus of any statements Y1 to Y4, wherein the health determination apparatus is further operable to:
   determine an impedance of the one or more cells based on the measured AC current and the measured AC voltage; and
   determine the measurement of the health of the battery based on the determined impedance.
Y6. The apparatus of any statements Y1 to Y5, wherein the health determination apparatus is further operable to:
   calculate RMS current and voltage values based on the measured AC current and the measured AC voltage, respectively; and
   calculate the measurement of the health of the battery based on the RMS current and voltage values.
Y7. The apparatus of any statements Y1 to Y6, wherein:
   the signal source is operable to cause the AC current to flow through the one or more cells, optionally wherein the signal source is external to or separate from the battery; and/or
   the signal source is configured to superimpose the AC current on a DC current provided by the one or more cells and/or by the plurality N of series-connected cells.
Y8. The apparatus of statement Y7, wherein the signal source is coupled to terminals of the battery, or to the one or more cells, to cause the AC current to flow through the one or more cells, optionally using a switch.
Y9. The apparatus of statement Y8, wherein the signal source is coupled to the terminals of the battery, or to the one or more cells, via a DC decoupling component or an AC coupling component, that component optionally comprising a capacitor and/or a transformer.
Y10. The apparatus of any of statements Y1 to Y9, wherein the signal source causes the AC current to flow through the N series-connected cells.
Y11. The apparatus of statement Y10, wherein the health determination unit is further operable to:
   measure a plurality of AC voltages, each induced across a respective one or more cells of the N series-connected cells by the AC current; and
   determine a measurement of the health of the battery based on the measured AC current and at least two of the measured AC voltages.
Y12. The apparatus of statement Y11, wherein said plurality of AC voltages comprises N AC voltages each induced across a respective one of the N series-connected cells by the AC current.
Y13. The apparatus of statements Y12 or Y13, wherein the plurality of AC voltages are measured concurrently.
Y14. The apparatus of any of statements Y1 to Y13, wherein the signal source comprises:
   a totem-pole arrangement of transistors and a controller operable to control the transistors so that the totem-pole arrangement functions as an oscillator, the totem-pole arrangement optionally connected to a transformer; or
   an AC signal generator connected to an amplifier; or
   an inductor and a switch connected in series and a controller operable to control the switch so that the inductor and switch function as an oscillator.
Y15. The apparatus of statement Y1 or Y2, wherein:
   each cell of the N series-connected cells has a potential difference of V_{CELL};
   the battery has a potential difference of V_{B}=N*V_{CELL}; and
   the AC current is configured such that the peak-to-peak voltage V_{PP} of the AC signal is at least one order of magnitude smaller than V_{B},
   and optionally wherein:
      X is the ratio V_{B}/V_{PP}; and
      X≥10, or X≥20, or X≥100, or X≥200, or X≥400, or X≥800, or X≥N, or X≥2N, or X≥4N.
Y16. The apparatus of any of statements Y1 to Y15, comprising said battery.
Y17. A vehicle, or a propulsion unit or power unit therefor, or a power supply or containerized power supply, comprising the apparatus of any of statements Y1 to Y16, optionally wherein the vehicle is an aircraft, seacraft or spacecraft.
Z1. A method of determining the health of a battery comprising a plurality N of series-connected cells, the method comprising:
   causing an AC current to flow through one or more cells of the plurality of series-connected cells;
   measuring the AC current;
   measuring an AC voltage induced across the one or more cells by the AC current; and
   determining a measurement of the health of the battery based on the measured AC current and the measured AC voltage.
Z2. The method of statement Z1, wherein N≥20, or N≥50, or N≥100, or N≥200, or N≥400, or N≥800.
Z3. The method of statement Z1 or Z2, wherein:
   the N series-connected cells are connected in series between terminals of the battery and configured, when charged, to generate a potential difference V_{B} across the battery terminals; and
   the AC current is configured such that the peak-to-peak voltage V_{PP} of the AC voltage is small compared to V_{B}.
Z4. The method of statement Z3, wherein X is the ratio V_{B}/V_{PP} and wherein:
   X≥100, or X≥200, or X≥400, or X≥800; and/or
   X≥N, or X≥2N, or X≥4N.
Z5. The method of any of statements Z1 to Z4, comprising:
   determining an impedance of the one or more cells based on the measured AC current and the measured AC voltage; and
   determining the measurement of the health of the battery based on the determined impedance.
Z6. The method of any of statements Z1 to Z5, comprising:
   calculating RMS current and voltage values based on the measured AC current and the measured AC voltage, respectively; and
   determining the measurement of the health of the battery based on the RMS current and voltage values.
Z7. The method of any of statements Z1 to Z6, comprising:
   using a signal source to cause the AC current to flow through the one or more cells, optionally wherein the signal source is external to or separate from the battery; and/or
   using a signal source to superimpose the AC current on a DC current provided by the one or more cells and/or by the plurality N of series-connected cells.
Z8. The method of statement Z7, comprising conductively coupling the signal source to terminals of the battery, or to the one or more cells, to cause the AC current to flow through the one or more cells, optionally using a switch.
Z9 The method of statement Z8, comprising conductively coupling the signal source to the terminals of the battery, or to the one or more cells, via a DC decoupling component or an AC coupling component, that component optionally comprising a capacitor and/or a transformer.
Z10. The method of any of statements Z1 to Z9, comprising causing the AC current to flow through the N series-connected cells.
Z11. The method of statement Z10, comprising:
   measuring a plurality of AC voltages, each induced across a respective one or more cells of the N series-connected cells by the AC current; and
   determining a measurement of the health of the battery based on the measured AC current and at least two of the measured AC voltages.
Z12. The method of statement Z11, wherein said plurality of AC voltages comprises N AC voltages each induced across a respective one of the N series-connected cells by the AC current.
Z13. The method of statement Z12 or Z13, comprising measuring the plurality of AC voltages concurrently.
Z14. The method of any of statements Z7 to Z9, wherein the signal source comprises:
   a totem-pole arrangement of transistors and a controller operable to control the transistors so that the totem-pole arrangement functions as an oscillator, the totem-pole arrangement optionally connected to a transformer; or
   an AC signal generator connected to an amplifier; or
   an inductor and a switch connected in series and a controller operable to control the switch so that the inductor and switch function as an oscillator.
Z15. The method of statement Z1 or Z2, wherein:
   each cell of the N series-connected cells has a potential difference of V_{CELL};
   the battery has a potential difference of V_{B}=N*V_{CELL}; and
   the AC current is configured such that the peak-to-peak voltage V_{PP} of the AC signal is at least one order of magnitude smaller than V_{B}.
   and optionally wherein:
      X is the ratio V_{B}/V_{PP}; and
      X≥10, or X≥20, or X≥100, or X≥200, or X≥400, or X≥800, or X≥N, or X≥2N, or X≥4N.

1. Apparatus for determining the health of a battery comprising a plurality N of series-connected cells, the apparatus comprising:
an AC signal source operable to cause an AC current to flow through one or more cells of the plurality of series-connected cells;
a current measurement unit operable to measure the AC current;
a voltage measurement unit operable to measure an AC voltage induced across the one or more cells by the AC current; and
a health determination unit operable to determine a measurement of the health of the battery based on the measured AC current and the measured AC voltage.

2. The apparatus of claim 1, wherein N≥20, or N≥50,
or N≥100, or N≥200, or N≥400, or N≥800.

3. The apparatus of claim 1, wherein:
the N series-connected cells are connected in series between terminals of the battery and configured, when charged, to generate a potential difference V_{B} across the battery terminals; and
the AC current is configured such that the peak-to-peak voltage V_{PP} of the AC voltage is small compared to V_{B}.

4. The apparatus of claim 3, wherein X is the ratio V_{B}/V_{PP} and wherein:
X≥100, or X≥200, or X≥400, or X≥800; and/or
X≥N, or X≥2N, or X≥4N.

5. The apparatus of claim 1, wherein the health determination apparatus is further operable to:
determine an impedance of the one or more cells based on the measured AC current and the measured AC voltage; and
determine the measurement of the health of the battery based on the determined impedance.

6. The apparatus of claim 1, wherein the health determination apparatus is further operable to:
calculate RMS current and voltage values based on the measured AC current and the measured AC voltage, respectively; and
calculate the measurement of the health of the battery based on the RMS current and voltage values.

7. The apparatus of claim 1, wherein:
the signal source is operable to cause the AC current to flow through the one or more cells, optionally wherein the signal source is external to or separate from the battery; and/or
the signal source is configured to superimpose the AC current on a DC current provided by the one or more cells and/or by the plurality N of series-connected cells.

8. The apparatus of claim 7, wherein the signal source is coupled to terminals of the battery, or to the one or more cells, to cause the AC current to flow through the one or more cells, optionally using a switch.

9. The apparatus of claim 8, wherein the signal source is coupled to the terminals of the battery, or to the one or more cells cells, via a DC decoupling component or an AC coupling component, that component optionally comprising a capacitor and/or a transformer.

10. The apparatus of claim 1, wherein the signal source causes the AC current to flow through the N series-connected cells.

11. The apparatus of claim 10, wherein the health determination unit is further operable to:
measure a plurality of AC voltages, each induced across a respective one or more cells of the N series-connected cells by the AC current; and
determine a measurement of the health of the battery based on the measured AC current and at least two of the measured AC voltages.

12. The apparatus of claim 11, wherein the plurality of AC voltages comprises N AC voltages each induced across a respective one of the N series-connected cells by the AC current.

13. The apparatus of claim 1, wherein the signal source comprises:
a totem-pole arrangement of transistors and a controller operable to control the transistors so that the totem-pole arrangement functions as an oscillator, the totem-pole arrangement optionally connected to a transformer; or
an AC signal generator connected to an amplifier; or
an inductor and a switch connected in series and a controller operable to control the switch so that the inductor and switch function as an oscillator.

14. The apparatus of claim 1, comprising said battery the battery.

15. A vehicle, or a propulsion unit or power unit therefor,
or a power supply or containerized power supply, comprising the apparatus of claim 1, optionally wherein the vehicle is an aircraft, seacraft or spacecraft.

16. A method of determining the health of a battery comprising a plurality N of series-connected cells, the method comprising:
causing an AC current to flow through one or more cells of the plurality of series-connected cells;
measuring the AC current;
measuring an AC voltage induced across the one or more cells by the AC current; and
determining a measurement of the health of the battery based on the measured AC current and the measured AC voltage.

17. The method of claim 16, wherein N≥20, or N≥50, or N≥100, or N≥200, or N≥400, or N≥800.

18. The method of claim 16, or claim 16 wherein N≥20, or N≥50, or N≥100, or N≥200, or N≥400, or N≥800; and wherein:
the N series-connected cells are connected in series between terminals of the battery and configured, when charged, to generate a potential difference V_{B} across the battery terminals; and
the AC current is configured such that the peak-to-peak voltage V_{PP} of the AC voltage is small compared to V_{B}.

19. The method of claim 18, wherein X is the ratio V_{B}/V_{PP} and wherein:
X≥100, or X≥200, or X≥400, or X≥800; and/or
X≥N, or X≥2N, or X≥4N.

20. The method of claim 16, comprising:
determining an impedance of the one or more cells based on the measured AC current and the measured AC voltage; and
determining the measurement of the health of the battery based on the determined impedance.
